(19) United States
(12) Patent Application Publication
(10) Pub. No.: US 2022/0269177 A1
(43) Pub. Date: Aug. 25, 2022

(54) SENSOR TECHNOLOGY INTEGRATION INTO COATING TRACK

(71) Applicant: Tokyo Electron Limited, Tokyo (JP)

(72) Inventors: Michael Carcasi, Austin, TX (US); Joshua Hooge, Austin, TX (US); Masashi Enomoto, Kumamoto (JP); Masahide Tadokoro, Kumamoto (JP); Kazuhiro Shiba, Kumamoto (JP)

(21) Appl. No.: 17/183,138

(22) Filed: Feb. 23, 2021

(51) Int. Cl. G03F 7/16

(52) U.S. Cl. CPC G03F 7/162; G03F 7/168

(57) ABSTRACT

A method of processing a plurality of substrates includes loading a substrate onto a coating track, moving the substrate into a module of the coating track, performing a process to modify a film formed over the substrate, and obtaining, at a controller, optical sensor data from an optical sensor. The optical sensor data includes a measurement of a property of the film. The method includes determining a drying metric based on the property of the film, and adjusting a process parameter of the process based on the determined drying metric.

### TECHNICAL FIELD

The present invention relates generally to methods for film deposition, and, in particular embodiments, sensor technology integration into coating tracks.

### BACKGROUND

A variety of films are deposited by suspending a film matrix in a solvent, coating the film matrix solution onto a substrate, and then heating the substrate to drive off the solvent leaving a film coating.

The most widely used method of coating film solutions on semiconductor substrates is spin-coat deposition on a wafer in a coating track. A puddle of the film matrix solution is dispensed onto the center of the wafer. The wafer is then rotated at a series of rpm's to coat the wafer with a film coating of uniform thickness.

After the film coating is spin-coated onto the substrate it usually is baked in a post apply bake module (PAB) to drive off solvent and/or to induce a chemical reaction to alter a film property such as raising the glass transition temperature.

Specialized coating tracks are used to coat wafers with photosensitive films for photo lithography. In addition to the post apply bake (PAB) module, coating tracks include a post exposure bake module (PEB) and sometimes a post develop bake module (hard bake module).

Specialized coating tracks with a solvent anneal baker are used to process wafers in directed self-assembly (DSA) processes.

### SUMMARY

A method of processing a plurality of substrates includes loading a substrate onto a coating track, moving the substrate into a module of the coating track, performing a process to modify a film formed over the substrate, and obtaining, at a controller, optical sensor data from an optical sensor. The optical sensor data includes a measurement of a property of the film. The method includes determining a drying metric based on the property of the film, and adjusting a process parameter of the process based on the determined drying metric.

A method of processing a plurality of wafers includes loading a substrate into a module with a volatile organic compounds (VOC) sensor, processing the substrate in the module to modify a film formed over the substrate, obtaining VOC sensor data from the VOC sensor during the processing, and adjusting a process parameter of the processing at a controller based on the VOC sensor data.

A method of processing a plurality of wafers includes loading a substrate into a module with an edge bead sensor, processing the substrate in the module to modify a film formed over the substrate. The film includes an edge bead at an edge of the substrate. The method further includes obtaining edge bead sensor data from the edge bead sensor during the processing, and adjusting a process parameter of the processing at a controller based on the edge bead sensor data.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a block diagram showing major components of a coating track of a fabrication facility in accordance with an embodiment of the present invention;

FIG. 2 illustrates a block diagram showing major components of a coating track for coating photo resist in accordance with an embodiment of the present invention;

FIG. 3 is a cross sectional view of a spin-coating module from a coating track illustrated in FIG. 1 and FIG. 2 in accordance with an embodiment of the present invention;

FIG. 4 illustrates a graph of the rotational speed of a spin chuck with time in accordance with an embodiment of the present invention;

FIG. 5 illustrates a graph of optical sensor data with time of the intensity of light reflected from a film coating on a wafer in accordance with an embodiment of the present invention;

FIG. 6 illustrates a flow diagram describing methods of utilizing in-situ sensors to monitor and control the processes in a coating track in accordance with an embodiment of the present invention;

FIGS. 7A-7C illustrate cross sections describing edge bead rinse removal of film from the edge of a wafer in accordance with an embodiment of the present invention;

FIG. 8 illustrates a cross sectional view of a bake module from a coating track illustrated in FIG. 1 and FIG. 2 in accordance with an embodiment of the present invention;

FIG. 9 illustrates a graph of wafer temperature verses time with FDC segments added in accordance with an embodiment of the present invention;

FIG. 10 illustrates a graph of data from a volatile organic compounds (VOC) sensor versus time with FDC segments added in accordance with an embodiment of the present invention;

FIG. 11 illustrates a flow diagram describing embodiment methods of utilizing FDC with in-situ sensors to monitor and control the processes in a coating track in accordance with an embodiment of the present invention;

FIGS. 12A-12E illustrate cross-sectional views of the major processing steps in forming a pre-pattern plus directed self-assembly (DSA) sub lithographic pattern in accordance with an embodiment of the present invention; and

FIGS. 13A-13H illustrate cross-sectional views of the major processing steps in forming a chemioepitaxial self-assembly (DSA) sub lithographic pattern in accordance with an embodiment of the present invention.

### DETAILED DESCRIPTION OF ILLUSTRATIVE EMBODIMENTS

Various embodiments provide methods for controlling film processing in coating tracks. The film process control techniques described in this application are applicable to film processing of many different film materials on many different substrates. The film process control techniques described in this application are applicable to spin-coating films, edge bead removal of films from the edges of wafers, and post apply bake (PAB) of films in coating track equipment. For photo resist films, in addition to PAB, embodiment methods include post exposure bake (PEB), and a post develop bake (PDB) or hard bake. For directed self-assembly processes, embodiment methods include solvent anneal bake. The embodiments provided are compatible with and complementary to fault detection and control (FDC) systems and advanced process control systems (APC).

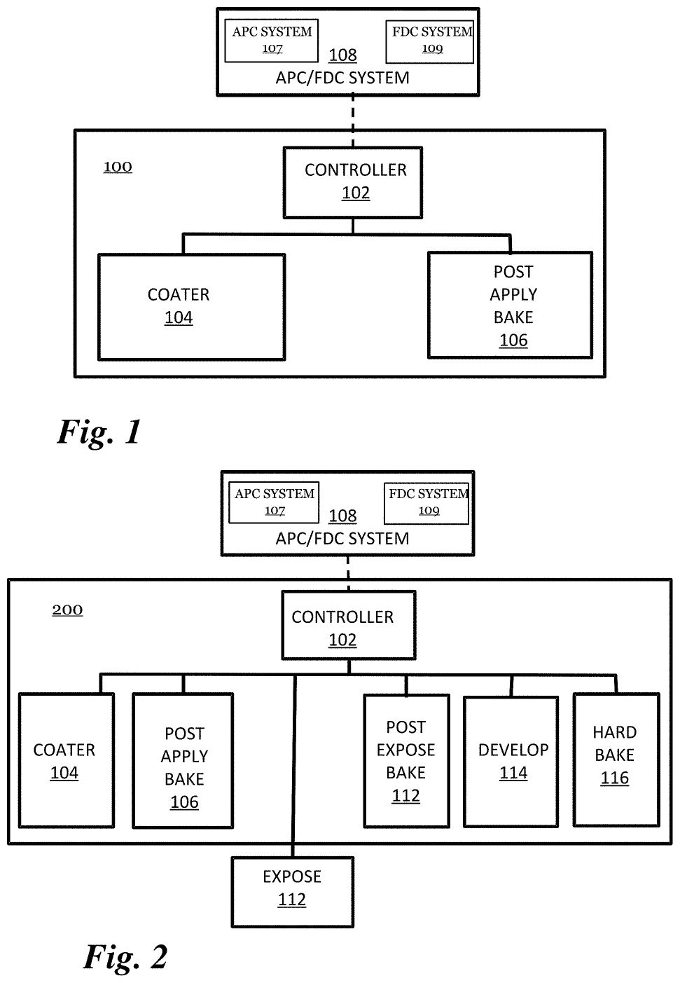

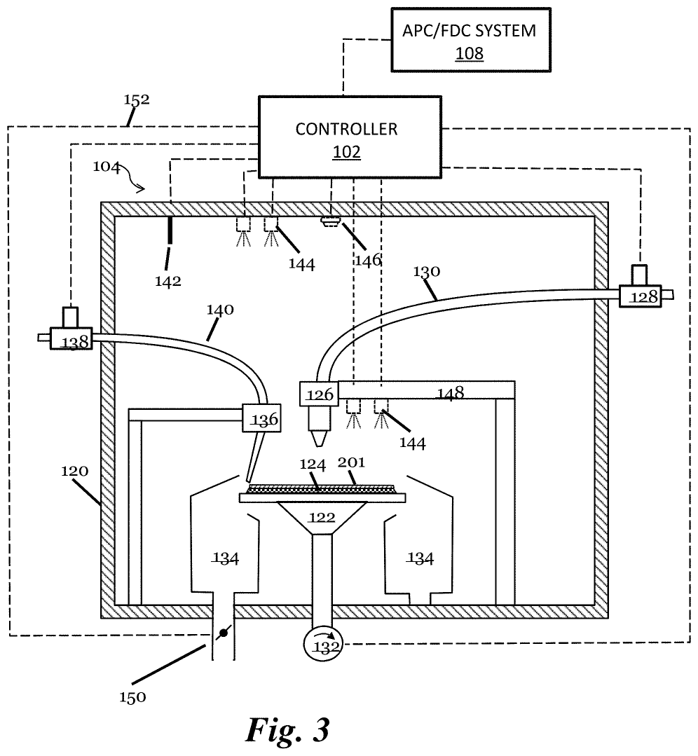

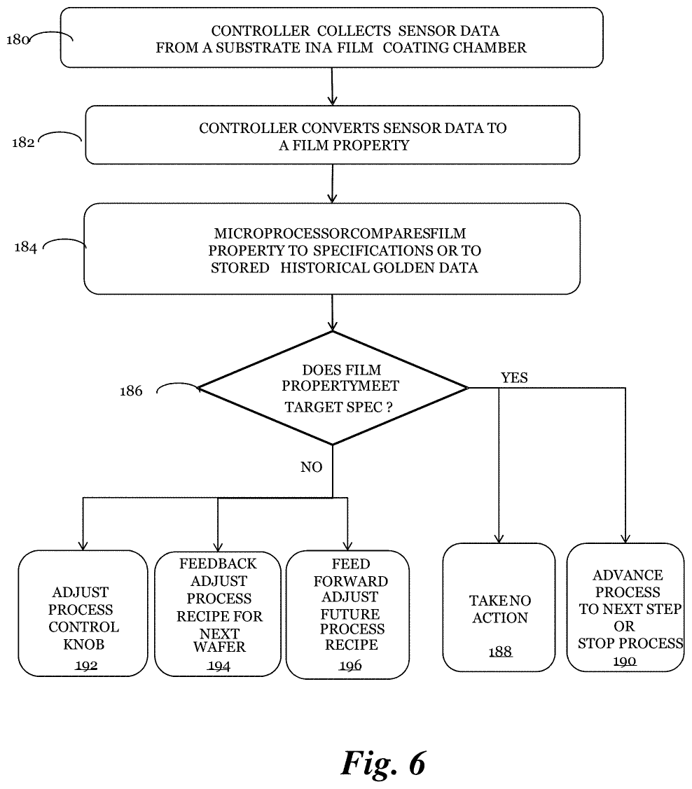

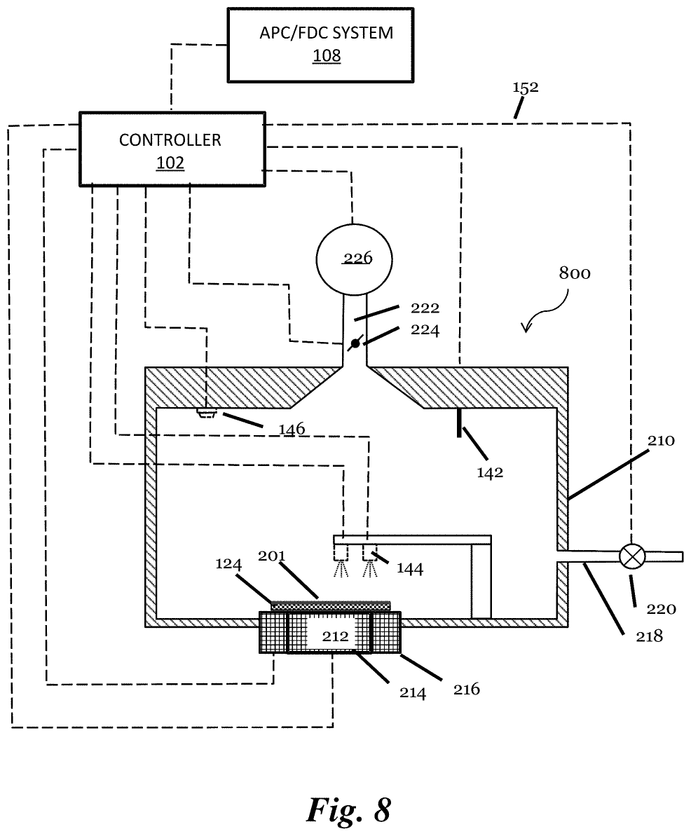

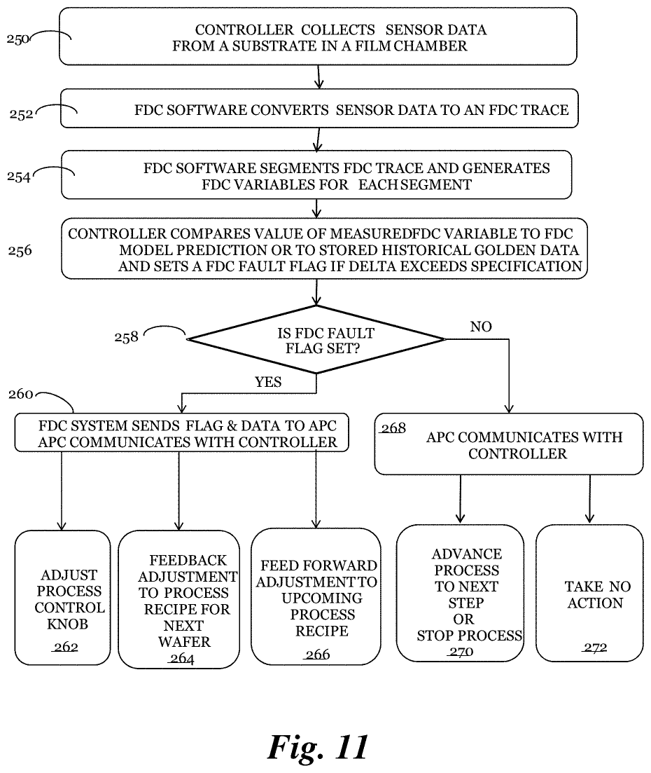

High level schematics of coating track systems using embodiments of the present application will be first described using FIGS. 1 and 2. A coating module implementing embodiments of the present application will then be described using FIG. 3 along with the flow chart of FIG. 6. Further embodiments of the process will be described using FIG. 11. A baking module implementing embodiments of the present application will then be described using FIG. 8 along with the flow chart of FIG. 6 and optionally FIG. 11.

FIG. 1 illustrates a block diagram of a coating track system 100 for film coatings. A coating module 104 dispenses a film solution onto a substrate and spins it at a series of revolutions per minute (rpms) to first cover the substrate with a uniform thickness of the film solution and then to cast off excess film solution until a film coating with a target thickness and uniformity is achieved. The coating track system 100 then advances the substrate to a post apply bake (PAB) module 106 where the film coating is baked to drive off excess solvent. In some arrangements, after the solvent concentration is reduced to an acceptable level, a higher temperature can be used to initiate chemical crosslinking reactions to improve the chemical and thermal stability of the film coating.

The controller 102 receives coating module 104 status data such as temperature, pumping speed, dispense nozzle position, spin chuck rpm and also data from coating sensors that monitor various properties of the film as it is being coated.

The controller 102 also receives post apply bake (PAB) module 106 status data such as temperature, pressure, exhaust flow rate, substrate zone temperature data and also receives data from bake sensors that monitor various properties of the film and various properties of the ambient as the film is being baked.

The controller can compare the sensor data to control chart limits and make adjustments in real time to the process, provide feedback instructions for future wafers, and provide feedforward instructions for subsequent process steps in current module process or future processes.

The controller can also convert the sensor data to film parameters such as film thickness, solvent content, and index of refraction and compare these parameters to control chart limits and make adjustments to the process or terminate the current processing step or current process.

The controller 102 is compatible with and can be connected to an advanced process control (APC) system 107 and a fault detection and classification (FDC) system 109. The APC system 107 and FDC system 109 can be integrated into a combined APC/FDC system 108. The controller 102 can provide data to and receive processed data and instructions from the APC/FDC system 108. An APC/FDC system 108 can collect massive amounts of process, metrology, and sensor data from multiple tools across a manufacturing line; perform sophisticated statistical analysis to identify statistically significant correlations between sensor data from the controller 102 and data from other manufacturing equipment and processes. The APC/FDC system 108 can generate sophisticated models which include data provided by the controller 102 and can optimize electrical device performance by adjusting process parameters across multiple manufacturing modules and equipment. For example, the APC/FDC system 108 could identify a correlation between a dielectric film stress and transistor performance and send feedback information to the controller 102 to adjust a dielectric film coating process that changes stress to improve the transistor performance.

The FDC system 109 can compare results of the FDC analysis to specifications or to known good historical data (golden data) and set a FDC fault flag when a process fault is identified. The FDC system 109 can communicate the fault and supporting data to the APC system 107. The APC system 107 can send processed data and instructions to the controller 102. The controller 102 adjusts processes on the coating track system 100 to fix the fault. The controller 102 can also take action to prevent the fault from occurring on future wafers and can take action on a subsequent process to compensate for the fault and bring the film closer to center of specification.

FIG. 2 illustrates a block diagram of a coating track system 200 for coating photo active films such as photo resists. After the photo resist is applied to the substrate in the coating module 104 it is processed through a number of additional processing steps in several modules such as an expose module 110 to print a pattern in the resist and a develop module 114 to wash away exposed resist and leave photo resist film pattern geometries remaining. After each process step, the photo resist can be baked. After coating, a post apply bake (PAB) can be performed in a PAB module 106 to drive off excess solvent. After exposure in the expose module 110, a post exposure bake (PEB) can be performed in a PEB module 112 to drive chemical reactions in the chemically amplified photo resist. After developing in the develop module 114, for some manufacturing processes, a post develop bake or hard bake can be performed to cross link the resist so it can withstand higher processing temperatures. During directed self-assembly processing, a solvent anneal bake can be performed in a solvent anneal baker to segregate the block copolymers into a repeating pattern.

The controller 102 receives data from sensors that monitor the equipment such as spin chuck rpm and valve or mass flow controller position, and also from sensors that monitor the process such as optical sensors, volatile organic compound (VOC) concentration, exhaust flow, temperature, and pressure. The controller 102 can compare the sensor data to control chart specifications or to historical known good data range (golden range), can make an adjustment in real time to the process, can provide feedback instructions for future wafers, and can provide feedforward instructions for upcoming processes.

The controller 102 can be connected to an advanced process control (APC) system 107, and a fault detection and classification (FDC) system 109. The APC system 107 and the FDC system 109 can be integrated into an APC/FDC system 108. The controller 102 can provide data to and receive processed data, instructions, plus other feedback information from the APC/FDC system 108. For example, the APC/FDC system 108 could find a correlation between line edge roughness (LER) on a photoresist geometry and a PEB step temperature or bake duration. The APC/FDC system 108 could provide feedback information to the controller 102 to adjust the PEB recipe to reduce LER.

FIG. 3 is a cross sectional view of a coating module 104. A substrate 124 is held in place on a spin chuck 122 by vacuum or electrostatics. A mass flow controller 128 controls the flow of the film solution through a tube 130 to a dispense nozzle 126. The dispense nozzle 126 dispenses film solution onto the substrate 124 as the spin chuck 122 rotates. As the substrate 124 spins, the film solution is spread uniformly across the substrate 124. Excess film solution is cast off the edges of the substrate 124 and collected by the film solution cup 134. A uniform coating of the film 201 is formed across the surface of the substrate 124.

Sensors such as optical sensors 144 and volatile organic compounds (VOC) sensors 146 can be mounted on the ceiling of the coating chamber 120 and can be mounted on the support arm 148 of the dispense nozzle 126 to monitor the film 201 throughout the coating process. The optical sensors 144 can be directed at various locations across the surface of the substrate 124 including the outer edge of the substrate 124 where an edge bead can be removed. Light from a laser can be projected into the coating module 104 from the side of the coating chamber 120 and redirected with normal incidence onto the surface of the film 201 on the substrate 124. The reflected light can be collected on the opposite side of the coating module 104 or can be reflected back through the film 201 a second time from another mirror. The optical sensor 144 can be a camera, a spectrometer, and/or a laser-based transceiver. The VOC sensor 146 can be a small form factor gas sensor such as the ADA fruit MiCS554 sensor for example.

The controller 102 can correlate a changing interference pattern (FIG. 5) from an optical sensor 144 in the coating module 104 to changing thickness of the film 201. Using this data the controller 102 can adjust the spin speed of the spin chuck 122 to control the changing thickness of the film 201 or to stop the spin chuck 122 when a target thickness is reached for the film 201.

The concentration of volatile organics in the coating module 104 changes throughout the coating process. Using VOC data from a VOC sensor 146 the controller 102 can adjust the spin speed of the spin chuck 122 to control the changing concentration of volatile organics in the coating module 104 or to stop the spin chuck 122 when a target VOC concentration is reached.

The controller 102 can be connected to 152 and receive data from the film monitoring sensors, i.e., optical sensor(s) 144, and VOC sensor 146. The controller 102 can also be connected to and receive data regarding the status of various components in the coating module 104 such as mass flow controller 128, edge bead rinse mass flow controller 138, spin chuck 122 motor 132 and exhaust valve 150. In addition to receiving data regarding the status of the various equipment components, the controller 102 can make adjustments such as turning pumps ON and OFF, adjusting the dispense rate by adjusting the mass flow controllers 128 and 138, adjusting dispense nozzle 126 position, changing the rpm's of the spin chuck 122 by adjusting the motor 132, adjusting the position of the exhaust valve 150, among others. The controller 102 can also be connected to an integrated advanced process control/fault detection and classification system (APC/FDC) 108.

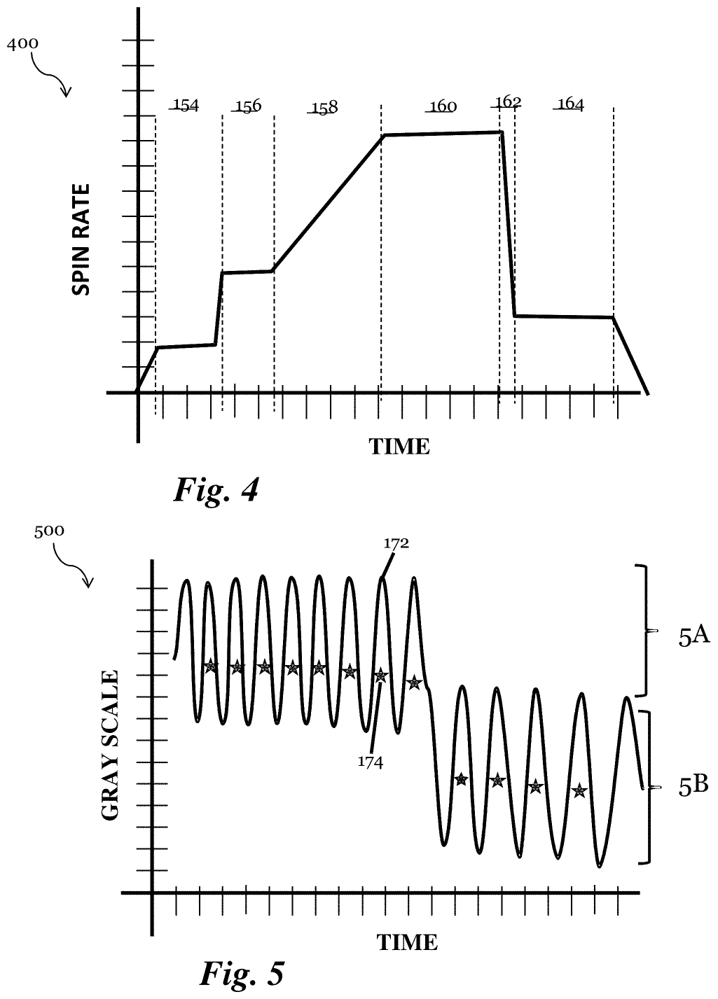

Process control by utilizing data from an optical sensor 144 in a coating module 104 in a coating track system 200 is illustrated with graphs in FIGS. 4 and 5. Process control of the coating module 104 by the controller 102 using data gathered from sensors such as optical sensors 144 and VOC sensors 146 in the coating chamber 120 is illustrated in the flow diagram in FIG. 6.

FIG. 4 illustrates a graph of the rotational speed of the spin chuck 122 (rpms) versus time in a film coating recipe. FIG. 4 will be described along with the coating module 104 of FIG. 3.

In step 154 in FIG. 4, a puddle of film solution is dispensed onto the middle of the substrate 124 while the spin chuck 122 spins at a low spin speed. The rotational rpm of the substrate 124 is then increased in step 156 and maintained at the increased rpm to uniformly spread the puddle across the entire substrate 124. Once a uniform coating of the film solution is achieved, the rotational speed of the spin chuck 122 is ramped up in a precisely controlled manner in step 158 to reduce the thickness of the film 201 by casting excess film solution off the edges of the substrate 124 and into the film solution cup 134. The higher rpm rate is maintained in step 160 until a specified film 201 thickness is attained. Once the desired thickness is reached, the rpm of the spin chuck 122 is ramped down in step 162 and then is kept at a lower rpm in step 164 while excess solvent is evaporated. An optical sensor 144 can be used to measure the thickness of the film 201 and the solvent content of the film 201 throughout the spin coat process. A VOC sensor 146 can be used to measure the concentration of solvent within the coating module 104 as it changes throughout the spin coat process. The change in concentration of solvent can be correlated to properties of the film 201 such as solvent content and can be correlated to changes in processing steps such as changes in spin speed.

FIG. 5 is example sensor data from a laser based transceiver optical sensor 144. As the thickness of the film 201 is reduced, light reflecting from the bottom surface of the film 201 interferes alternatively constructively and destructively with light reflected from the top surface of the film 201. The resultant interference pattern of grey scale intensity alternating through maxima and minima versus time is illustrated in FIG. 5. The controller 102 can correlate the time period between the peaks 172, or the peak centroids 174 to the thickness of the film 201 and to the rate at which the thickness of the film 201 is changing. As the decrease in thickness of the film 201 slows down, the spacing between the peaks 172 and the peak centroids 174 increases. The gray scale intensity of the interference fringes can change when the spin speed of the spin chuck 122 is changed. This can result in a shift of the interference fringes along the vertical y-axis when the rpm of the spin chuck 122 changes. (Compare the 5A group of interference fringes to group 5B in FIG. 5.)

The controller 102 can correlate a change of the index of refraction to the solvent content of the film 201 and in this manner can establish a film drying metric.

FIG. 6 illustrates an example of control of the process within the coating track systems 100 and 200 such as are described in FIGS. 1 and 2 utilizing sensor data in accordance with an embodiment of the present application. The controller 102 can collect sensor data from an optical sensor 144, from a volatile organic compounds (VOC) sensor 146, or from both optical sensors 144 and VOC sensors 146 as well as other sensors. It is noted that the optical sensor 144 can be used independent of the VOC sensor 146 in one embodiment while in another embodiment the optical sensor 144 and the VOC sensor 146 may be used in conjunction. The controller 102 can determine the rate at which the film 201 thickness is changing and the rate at which the solvent content of the film 201 is changing during the spin coating process using optical sensor 144 data. The rate at which solvent is evaporating from the film 201 during the coating process can be determined from the VOC sensor 146 data. The solvent content of the film 201 during the spin coating process can be correlated to the VOC sensor 146 data and correlated to the optical sensor 144 data as well.

Referring now to FIG. 6, the film 201 on the substrate 124 in the coating module 104 is monitored during each step of the spin coating process. (Step 180, FIG. 6).

Data from a laser-based transceiver optical sensor 144 is illustrated in FIG. 5. The controller converts the optical sensor 144 data to a film 201 property such as thickness and solvent content (Step 182, FIG. 6).

The controller 102 can receive data from several optical sensors 144 spaced above the substrate 124 and convert the data to the across substrate film uniformity properties such as film thickness, index of refraction, and solvent content. The controller 102 can compare this data to historically stored known good data (golden data) or to a control chart (step 184, FIG. 6) and can perform various actions depending upon determining whether the film 201 property or film 201 uniformity is in or out of specification (Step 186, FIG. 6). In response to determining that the film 201 property is in specification no action is taken (step 188, FIG. 6). In response to determining that the film 201 property hits a target spec, the controller 102 may terminate the process or may advance the process to the next process step. (Step 190, FIG. 6). The next step can be the next step in the coating process such as a change to spin speed or can be a change to a recipe in a following process procedure such as the post apply bake (PAB).

In response to determining that the film 201 property is in a warning state or is out of specification, an adjustment can be made in real time to the process to bring the film 201 thickness closer to center of specification (Step 192, FIG. 6). For example, in the coating module 104 the controller 102 can adjust the dispense nozzle 126 position, the film dispense rate, the film coating spin speed, the coating speed ramp rate, the film coating step duration, the film coating cast time, an ambient condition, and an exhaust condition. The controller 102 can also make feedback adjustments to the film dispense recipe prior to coating the next substrate 124 (step 194, FIG. 6) and can make feed forward adjustments to the edge bead rinse process step in the current coat procedure or to the upcoming bake recipe before the current substrate 124 is transferred into the post apply bake (PAB) module 106 (step 196, FIG. 6).

The optical sensor 144 can pick up a failure condition such as an air bubble during dispense. An air bubble during dispense on the substrate 124 can significantly alter the flow of the coating film as the wafer spins. The bubble creates significant deviations from the typical signal resulting in discontinuous signal jumps in interference fringes or high increases in signal noise. The dispense bubble results in a significantly non-uniform coating. When the APC/FDC system 108 or the controller 102 identifies such a substrate 124 the coating process is terminated and the substrate 124 is sent to rework.

After a film 201 is uniformly coated on a substrate 124, the outer few millimeters at the edge of the substrate 124 (edge bead rinse (EBR) can be removed to prevent a wafer from rubbing against slots in wafer carriers or wafer handling equipment and generating particles that could reduce process yield.

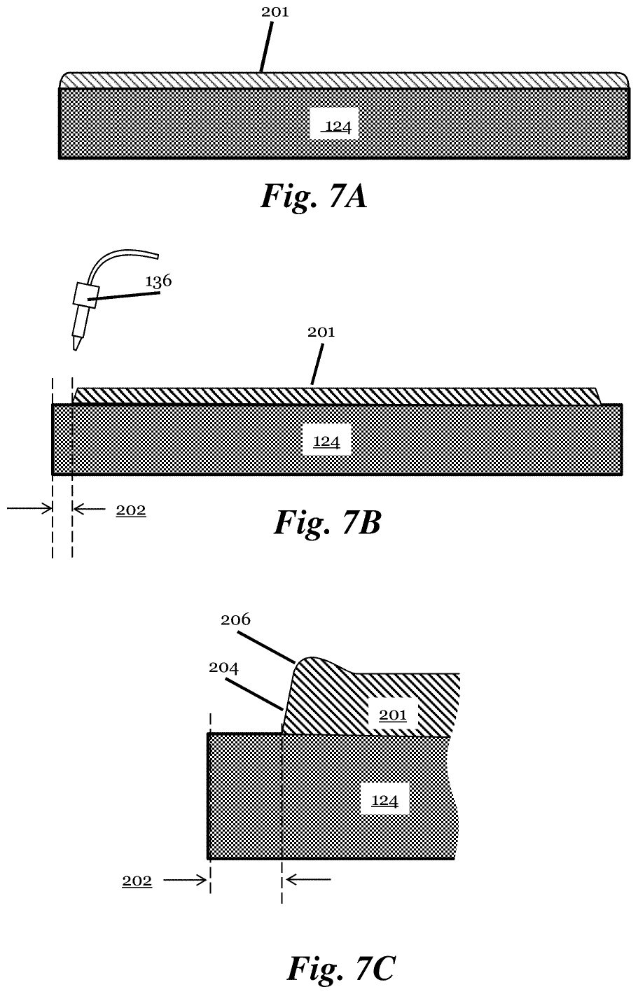

FIG. 7A illustrates a cross sectional view of a substrate 124 after applying a film 201. The film 201 covers the surface of the substrate 124 and extends to the edge of the substrate 124.

As is illustrated in FIG. 7B, an EBR dispense nozzle 136 directs a stream of solvent to rinse the film 201 from the outer few millimeters of edge of the substrate 124. This process is called edge bead rinsing (EBR) or edge bead removal. The width of the edge of the substrate 124 that is cleared of film 201 is the edge bead width 202.

An expanded cross sectional view of the sidewall 204 of the film 201 after EBR is shown in FIG. 7C. The exposed sidewall 204 can be affected by the EBR and form an edge bead hump 206 around the perimeter of the film 201. Physical force from the solvent stream during EBR can further increase the height of edge bead hump 206. The edge bead hump 206 is undesirable because it distorts device patterns and device geometries near the edge of the substrate 124 resulting in nonworking circuits and reduced yield.

Optical sensors 144 can monitor the edge bead hump 206 parameters as edge bead hump position, edge bead hump height, and edge bead removal width throughout the EBR process. The controller 102 can relate coater data such as the position and orientation of the EBR dispense nozzle 136, EBR dispense rate, EBR step rpm, EBR scan in rate, and EBR cast time to edge bead parameters such as edge bead width 202, edge bead hump 206 position and height derived from optical sensor 144 data. The controller 102 can then make adjustments to the EBR dispense nozzle 136 position and angle, and to the EBR dispense rate, the EBR scan in rate, the EBR step rpm, and the EBR cast time to adjust the edge bead width 202 of the edge bead removed, and adjust slope of the sidewall 204 of the edge bead hump 206.

FIG. 8 illustrates a cross sectional view of a bake module 800 in accordance with an embodiment of the present application. This could be a post apply bake (PAB) module 106 in a coating track systems 100 and 200, or a post-exposure bake (PEB) module 112 or a hard bake module 116 in a coating track system 200, for example. This could also be a solvent anneal baker used during direct self-assembly processing.

The controller 102 can correlate the changing interference pattern (FIG. 5) from an optical sensor 144 in the bake module 800 to changing thickness of the film 201. Changes in film thickness of the film 201 in the bake module 800 are not as large as in the coating module 104. The interference pattern (FIG. 5) from a laser transceiver in a bake module 800 may be just a couple of interference fringes or may be a partial fringe. Using this data the controller 102 can adjust the temperature ramp rate, the bake temperature or the bake duration to control the changing film thickness. The controller 102 can terminate the bake when a target thickness of the film 201 is reached.

The concentration of volatile organic compounds in the bake module 800 changes throughout the bake process. Using the VOC concentration data, the controller 102 can adjust the temperature ramp rate, the bake temperature, and the bake duration to control the changing concentration of volatile organic compounds in the bake module 800. The controller 102 can terminate the bake process when a target VOC concentration is reached.

A substrate 124 with a film 201 is placed on a bake plate 212 inside the bake module 800. The bake plate 212 can have a number of heater zones such as first zone 214 and second zone 216, whose temperature can be independently controlled. The substrate 124 and the film 201 can be heated to drive off solvent as in PAB, heated to drive chemical amplification reactions as in PEB, or heated to drive cross linking reactions as in hard bake. The bake process can be monitored in real time with sensors such as with an optical sensor(s) 144 or with a volatile organic compound (VOC) sensor(s) 146.

A controller 102 can collect sensor data from the optical sensor(s) 144 and/or the volatile organic compound (VOC) sensor(s) 146 as well as other sensors 142 such as ambient temperature sensors, ambient pressure sensors, and ambient gas flow sensors. The controller 102 can also be connected to line 152 and receive data regarding the status of various bake module components such as bulk facilities exhaust pressure 226, exhaust valve 224 position, bake plate 212, temperature of the first and second zones 214 and 216, and position of gas valve 220 for ambient intake 218. The controller 102 can receive data from and can make adjustments to these various bake module 800 components based upon data received from the film monitoring sensors. The controller 102 can be connected to an integrated advanced process control/fault detection and classification system (APC/FDC) 108.

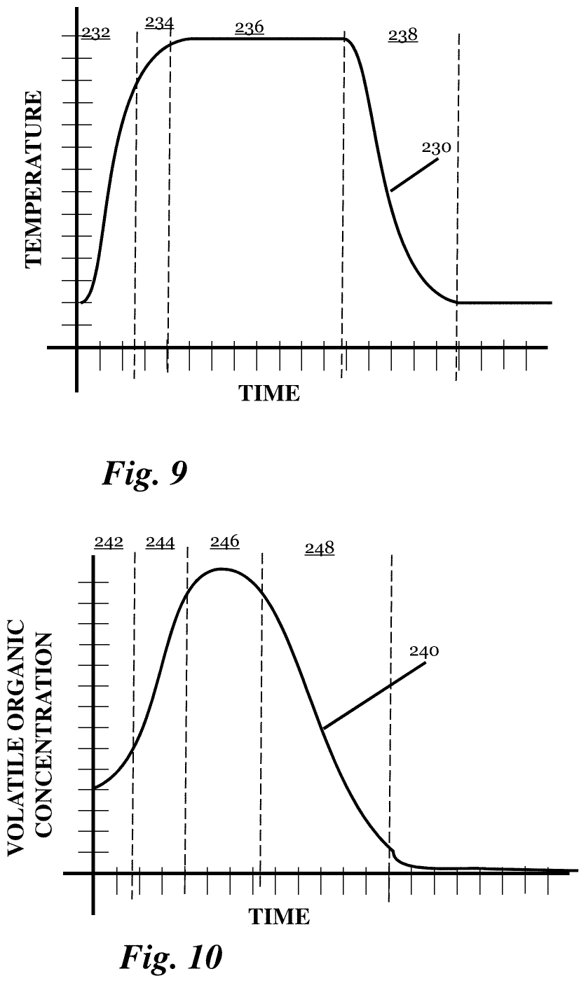

Process control of a bake process in a bake module 800 in which the controller 102 communicates with an advanced process control (APC)/fault detection and correction (FDC) system (APC/FDC system 108) is illustrated in the graphs in FIGS. 9 and 10. The flow diagram in FIG. 11 illustrates control of processes in a coating track system 200 using sensor data and a controller 102 in communication with an APC/FDC system 108 in accordance with embodiments of the invention. Sensor data from a volatile organic compound (VOC) sensor 146 is used for illustration, but optical sensor 144 data such as thickness and index of refraction data could equally well be used. Additionally, data from both optical sensors 144 and from VOC sensors 146 in the bake module 800 could be used to control the bake process in the bake module 800.

FIG. 9 is a graph showing the sensor temperature trace 230 of substrate 124 temperature sensor data versus time in bake module 800. FDC system's 109 software can segment the sensor temperature trace 230 and assign FDC variables to each segment. These FDC variables can be tracked and compared with FDC variable data gathered from other wafers and plotted in control charts. For example, first and second segments 232 and 234 monitor the temperature ramp and temperature stabilization of substrate 124 at the beginning of the bake process as the substrate 124 is ramped to the target bake temperature. For the first segment 232, FDC software can assign FDC variables such as start temperature, end temperature, temperature ramp rate, and temperature ramp time. For the third segment 236 which bakes the film until a target film property is achieved, FDC software may assign and monitor FDC variables such as start temperature, end temperature, maximum temperature, average temperature, minimum temperature and bake time.

During the film baking process, the controller 102 collects data from a VOC sensor 146 (step 250, FIG. 11) and communicates it to the FDC system 109. FDC software prepares a graph 240 (trace) of the VOC sensor data versus time (step 252, FIG. 11) as schematically illustrated in FIG. 10. The FDC software then segments the graph (trace) 240 of VOC data and assigns FDC variables to each segment (step 254, FIG. 11). During the rapid rise in substrate 124 temperature (first and second segments 232 and 234 (FIG. 9), the volatile organic compound concentration as measured by the volatile organic compound (VOC) sensor 146 rapidly rises as illustrated in VOC FDC segments 242 and 246 (FIG. 10). FDC variables in each of the VOC segments 242 and 244 can be FDC variables such as minimum concentration, maximum concentration, average concentration, maximum concentration rate of change, and segment time. While the substrate 124 is being baked at temperature in the third segment 236 (FIG. 9), the volatile organic compound concentration peaks in FDC segment 246 (FIG. 10) and then falls off. VOC FDC variables such as beginning concentration, peak concentration, maximum rate of concentration change, ending concentration, and segment duration can be assigned in VOC FDC segment 246. VOC FDC variables such as beginning concentration, concentration ramp down rate, ending concentration, and ramp down duration can be assigned in VOC FDC segment 248 where VOC concentration rapidly decreases.

FDC software can form a model that predicts FDC VOC concentration variable values throughout the substrate 124 baking process based upon FDC wafer temperature variable data received from the controller 102. For each VOC FDC segment, wafer temperature data can be used to predict FDC VOC variable values. Actual FDC VOC sensor data for the FDC VOC variables can be compared with predicted FDC VOC variable values or can be compared with historical known good “golden” VOC sensor data to determine if an FDC fault flag needs to be raised.

In response to determining that the FDC variable is in a warning state or is out of specification (Step 258, FIG. 11), the FDC system 109 raises an FDC fault flag and communicates it to the APC system 107 (Step 260, FIG. 11). The APC system 107 then communicates processed data and/or instructions to the controller 102 which in turn makes an adjustment to the process in real time to bring the FDC variable closer to center of specification or process window (Step 262, FIG. 11). For example, the controller 102 can adjust the bake temperature, bake temperature ramp rate, bake time, temperature of the substrate holder zone, and adjust an ambient condition such as ambient gas flow and ambient exhaust flow. The controller 102 can also provide feedback adjustments to the bake recipe prior to baking the next substrate 124 (step 266, FIG. 11) and provide feed forward adjustments to an upcoming step in the current recipe or to the recipe in a future processing step for the current substrate 124 (step 268, FIG. 11).

In one embodiment, the deviation that causes the FDC fault flag to be raised can be a predefined parameter, for example, a percent deviation from the predicted sensor data or historical golden VOC sensor data. This predefined percent deviation may be 10% in one embodiment but other embodiments may use different percent deviations between 1% and 20%.

In response to determining that the FDC variable is within specification, no FDC fault flag or sensor data is communicated to the APC system 107 (Step 268, FIG. 11). In this case , one option is to take no action (Step 272, FIG. 11)

If the FDC variable has reached a target value, no FDC fault flag is sent to the APC system 107 (Step 268, FIG. 11). In this event, the controller 102 can terminate the current process step and can advance the process to the next process step (step 270, FIG. 11). The next process step can be the next step in the baking process such as a cool down step or the next step can be to advance the substrate 124 to a resist develop module 114.

Film 201 monitoring and control in a coating track system 200 where the controller 102 is in communication with an APC/FDC system 108 is illustrated using a bake process. An FDC system 109 can be used to monitor every process running in a coating track system 200 and can raise an FDC fault flag when faults such as non-uniform coating, bubbles in the resist, and wedge wafers are detected.

The controller 102 can also receive data streams directly from an optical sensor 144 and directly from a volatile organic compound (VOC) sensor 146 and controller software can correlate changes in optical sensor data with changes in VOC sensor data. For example, the controller 102 may correlate a rapid change in the thickness of the film 201 or a rapid change of solvent in the film 201 from optical sensor data with changes in VOC sensor data.

Directed self-assembly (DSA) is a process whereby next generation sub-lithographic geometries can be formed using current generation lithography tools. This process involves the use of block copolymers which self-assemble into repeating patterns during thermal annealing processes that require precise control. Precise control of DSA anneals and solvent DSA anneals are provided by embodiments described. Solvent anneals can be performed in a solvent anneal baker that is specially designed for solvent anneal bakes and may be similar to the bake module 800 in some embodiments.

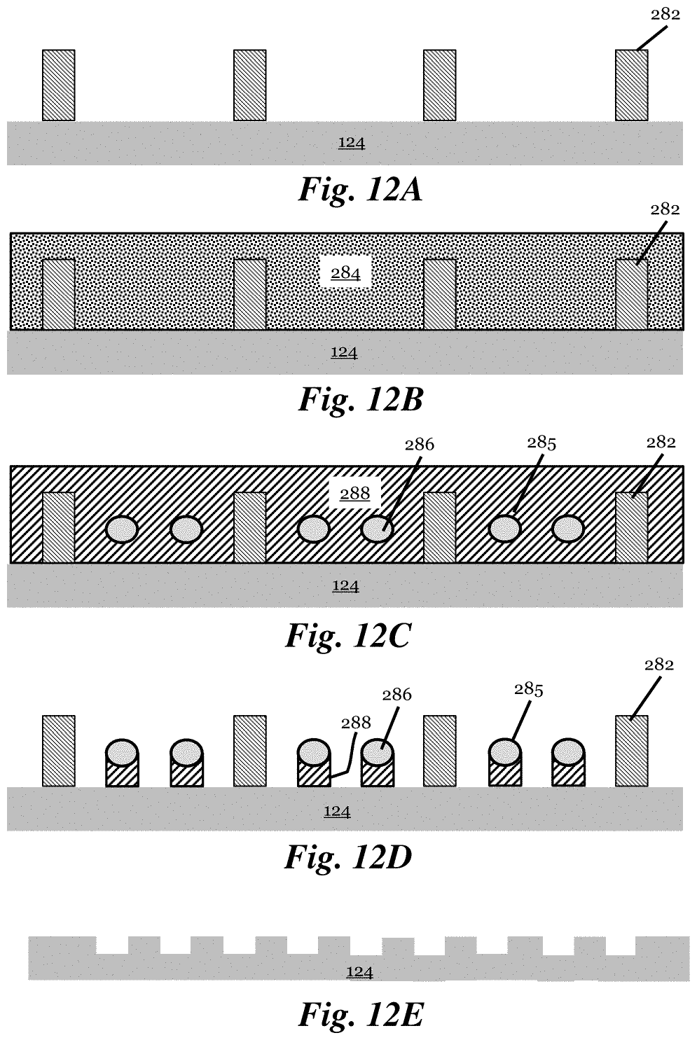

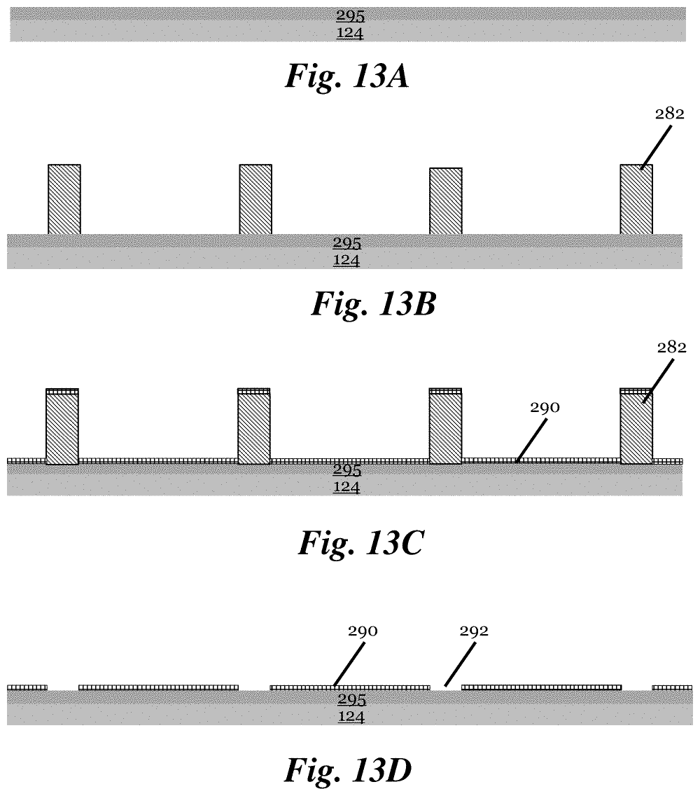

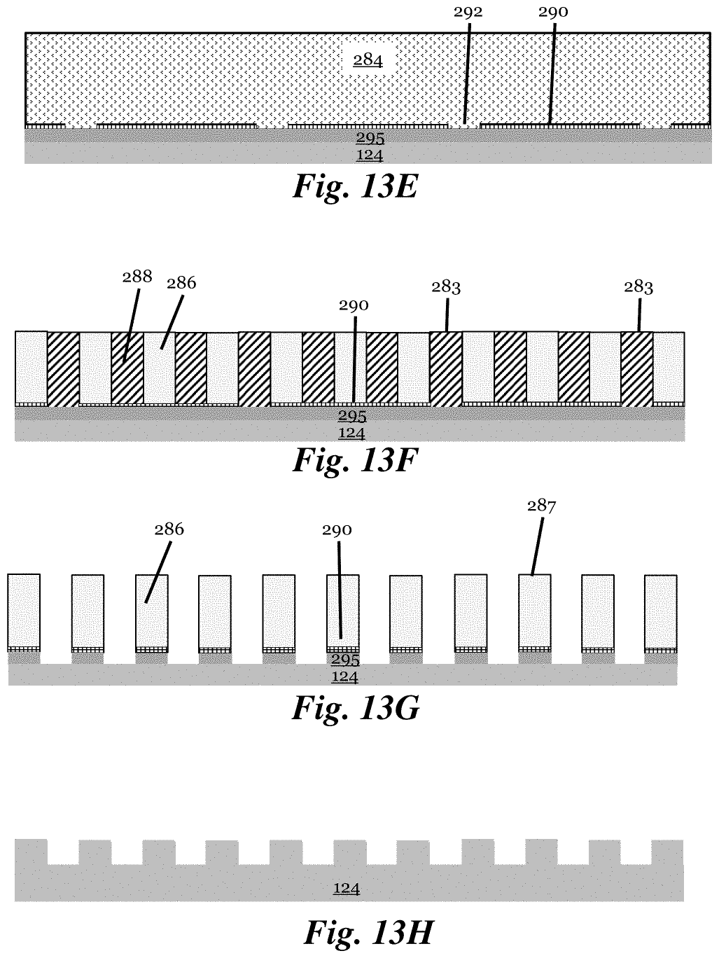

FIGS. 12A through 12E illustrate a graphoepitaxy directed self-assembly (DSA) patterning process to form sub lithographic patterns. FIGS. 13A through 13H illustrate a chemioepitaxy DSA patterning process for sub lithographic patterns. The DSA patterning process enables patterns with 20 nm line and space geometries or less to be formed using 193 nm lithography. The DSA coating method utilizes a mixture of two mutually repulsive block co polymers (BCP) such as PS-b-PMMA (poly(styrene-block-methyl methacrylate)).

Briefly, as illustrated in FIGS. 12A-12E, in the graphoepitaxy DSA process, pre-pattern geometries 282 formed on the substrate 124 constrain the BCP 284 to segregate into a regular pattern of separate BCP domains under carefully controlled solvent anneal baking conditions. The pre-pattern geometries 282 can constrain the BCP 284 to form lines and spaces, to form contact holes, or form whatever regularly spaced sub lithographic features might be desired. The molecular weight of the co polymers in the BCP 284 can be engineered to produce the desired DSA geometry size and geometry spacing.

In the chemioepitaxy DSA process illustrated in FIGS. 13A-13H, template surface geometries/energies that are compatible with one of the BCP components are formed on the substrate 124.

Frequently, the self-assembled sub lithographic patterns have defects and regions where they are not well formed after the BCP 284 is spin coated on the substrate. If possible, the BCP 284 is heated above the glass transition temperature to anneal out the defects and to segregate the block copolymer domains, e.g., first copolymer 286 and second copolymer 288, into the desired sub lithographic geometries. Frequently the BCP 284 thermally degrades before the glass transition temperature is reached. An alternative method is to introduce solvent vapor above the BCP 284 film in a solvent anneal baker. The solvent gets absorbed by the BCP 284 film causing it to swell. This increases the mobility of the BCP domains. Using a solvent anneal bake, the defects can be annealed out and the domain geometries fixed at a temperature well below where the BCP 284 is degraded. At the end of the solvent anneal bake, it is desirable to remove the solvent as quickly as possible to fix the sub lithographic geometries in place. Some BCPs require the solvent anneal bake process be repeated multiple times to eliminate all defects and to remove all irregularities from the DSA pattern. This requires a very carefully controlled solvent anneal bake procedure, which is enabled by embodiments of the present application.

The increase in BCP 284 thickness due to swelling during solvent anneal bake can be monitored using an optical sensor 144 such as a laser transceiver. The controller 102 can utilize the optical sensor data to control the solvent anneal bake process.

Alternatively, a VOC sensor 146 can monitor the concentration of the solvent in the solvent anneal baker throughout the solvent anneal bake process. The controller 102 can utilize the VOC data to control the solvent anneal process. For more precise control of the solvent anneal bake process, the controller 102 can use sensor data from both optical sensors 144 and VOC sensors 146 in the solvent anneal baker.

FIG. 12A illustrates regularly spaced pre-pattern geometries 282 on a substrate 124. These pre-pattern geometries 282 may be formed using 193 nm lithography. The substrate 124 may be a silicon substrate or may be another material such as silicon dioxide or metal. In a graphoepitaxy process, the substrate 124 is neutral to both block copolymer components, i.e., first copolymer 286 and second copolymer 288, in the BCP 284. The substrate 124 does not preferentially attract or repel either block copolymer component. The regularly spaced pre-pattern geometries 282, mask the substrate 124 during a subsequent BCP etch and during a subsequent substrate 124 etch.

In FIG. 12B, the substrate 124 and pre-pattern geometries 282 are coated with a solution of BCP 284. The solution of BCP 284 can be dispensed onto the substrate 124 using a coating track system 200.

FIG. 12C illustrates the BCP layer after a precisely controlled anneal bake is performed to cause the incompatible copolymers, i.e., first copolymer 286 and second copolymer 288, in the BCP 284 to segregate into separate block copolymer domains. Optical sensors 144 and/or VOC sensors 146 can be used to monitor and control the anneal bake process. If the anneal temperature needed to drive the self-assembly of the block copolymers is too high, a solvent anneal bake or a plurality of solvent anneal bakes can be performed.

In this illustrative example, one of the copolymers, i.e., first copolymer 286, segregates into regularly sized and regularly spaced cylinders 285 within a matrix of the other copolymer, i.e., second copolymer 288. The size and spacing of the cylinders 285 can be determined by the molecular weight of the block copolymers, i.e., first copolymer 286 and second copolymer 288, in the BCP 284 and by the size and spacing of the regularly spaced pre-pattern geometries 282. Optical sensors 144 can be used to monitor the status of the BCP 284 throughout the anneal process as the incompatible block copolymers, i.e., first copolymer 286 and second copolymer 288, segregate. The controller 102 in the coating track system 200 can adjust, in real time, the solvent anneal bake process as needed or can provide feedback instructions for the next substrate 124 or feedforward instructions for a future processing step.

In FIG. 12D, the matrix of the second copolymer 288 is etched anisotropically exposing the underlying substrate 124. The first copolymer 286 forming the cylinders 285 acts as an etch mask for the second copolymer 288 between it and the substrate 124. This graphoepitaxy process forms a sub lithographic pattern of equally sized lines and spaces.

FIG. 12E illustrates the substrate 124 after being etched with the regularly spaced pre-pattern geometries 282 and the cylinders 285 as an etch mask. The pre-pattern geometries 282 and the cylinders 285 are then removed.

FIGS. 13A through 13F describe an example chemioepitaxy DSA process. In a chemioepitaxy process the block copolymer (BCP) compatible layer 295 that is exposed in the spaces 292 in the neutral layer 290 attracts one of the block copolymer components, e.g., second copolymer 288 and repels the other, e.g., the first copolymer 286.

In FIG. 13A, a BCP compatible layer 295 that is compatible with the second copolymer 288 in the BCP 284 is deposited on a substrate 124. The substrate 124 may be a silicon substrate or another substrate such as silicon on insulator, silicon on glass, gallium arsenide, indium phosphide, silicon dioxide or metal. The BCP compatible layer 295 can be a hydrophobic layer to repel a hydrophilic block copolymer component or may be a hydrophilic layer to attract a hydrophilic block copolymer component.

In FIG. 13B, pre-pattern geometries 282 of photoresist are formed on the BCP compatible layer 295.

In FIG. 13C a neutral layer 290 is deposited on top of the pre-pattern geometries 282 and on top of the BCP compatible layer 295 that is exposed in the openings between the pre-pattern geometries 282. Very little or none of the neutral layer 290 is deposited on the sidewalls of the pre-pattern geometries 282. This can be accomplished using atomic layer deposition (ALD) or gas cluster ion beam (GCIB) deposition. Little to no neutral layer 290 on the sidewalls facilitates lift off processing. The neutral layer 290 is chosen so that it is compatible with both block copolymer components, i.e., first copolymer 286 and second copolymer 288, in the BCP 284. The neutral layer 290 does not preferentially attract or repel either BCP component, i.e., first copolymer 286 and second copolymer 288.

In FIG. 13D, pre-pattern geometries 282 are dissolved using a lift off process. This exposes the surface of the BCP compatible layer 295 in the spaces 292 (openings in the neutral layer 290).

In FIG. 13E, the neutral layer 290 and the BCP compatible layer 295 exposed in the spaces 292 are coated with the BCP 284 solution. The BCP 284 solution may be dispensed onto the substrate 124 using a coating track system such the coating track system 200 described earlier. One of the block copolymer components, e.g., second copolymer 288 in the BCP 284 solution is attracted to the BCP compatible layer 295 exposed in the spaces 292 in the neutral layer 290 and the other block copolymer component, e.g., first copolymer 286 is repelled.

FIG. 13F illustrates the BCP 284 layer after a precisely controlled solvent anneal bake is performed, e.g., in a solvent anneal baker. Some BCPs may need a plurality of solvent anneal bakes. During the solvent anneal bake, the compatible BCP component, e.g. second copolymer 288 is attracted to the BCP compatible layer 295 exposed in the spaces 292 in the neutral layer 290. The geometries 283 of the second copolymer 288 that form in the spaces 292 are pinned to the underlying BCP compatible layer 295. The pinned second copolymer 288 constrains the two incompatible BCP components, i.e., first copolymer 286 and second copolymer 288, to segregate into a regular pattern of separate BCP domains over the exposed neutral layer 290.

FIG. 13G shows the first copolymer remaining after an etch process that removes the second copolymer 288. This etch process may also etch through the underlying neutral layer 290, through the BCP compatible layer 295, and stop on the underlying substrate 124. The etch process does not etch or remove the first copolymer 286 that can be used as a hard mask 287 to etch the pattern into the underlying substrate 124.

FIG. 13H shows the device being fabricated after patterning the substrate 124 with the hard mask 287 and the subsequent removal of any remaining hard mask 287 along with underlying layers such as the neutral layer 290, and the BCP compatible layer 295. Precise control of the DSA processes throughout the DSA coating process and during the DSA solvent anneal bake is critical to the chemioepitaxy DSA process.

Embodiment methods describe a controller in a coating track systems 100 and 200 gathering data from film process monitoring sensors such as optical sensors 144 and volatile organic compound sensors 146 and using this data to control various aspects of the coating track systems, 100 and 200 throughout the coating and baking processes, particularly, during the DSA coat and the DSA solvent anneal bake processes.

Example embodiments of the invention are summarized here. Other embodiments can also be understood from the entirety of the specification as well as the claims filed herein.

### EXAMPLE 1

A method of processing a plurality of substrates includes loading a substrate onto a coating track, moving the substrate into a module of the coating track, performing a process to modify a film formed over the substrate, and obtaining, at a controller, optical sensor data from an optical sensor. The optical sensor data includes a measurement of a property of the film. The method includes determining a drying metric based on the property of the film, and adjusting a process parameter of the process based on the determined drying metric.

### EXAMPLE 2

The method of example 1, where adjusting the process parameter includes: providing a feed back signal to adjust the process parameter for processing a subsequent substrate, determining an end point of the processing and terminating the processing, providing a feed forward signal to adjust a recipe for a subsequent process for the substrate, and providing a feed forward signal to adjust a recipe for a current process.

### EXAMPLE 3

The method of one of examples 1 or 2, where the module includes a coating module, a bake module, or a solvent anneal baker.

### EXAMPLE 4

The method of one of examples 1 to 3, where performing the process includes performing a directed self-assembly (DSA) coating process, and where adjusting the process parameter of the process includes adjusting a solvent saturation time, a solvent saturation temperature, a solvent saturation concentration, a solvent evacuation initiation time, a solvent evacuation rate, a solvent evacuation duration, a DSA exhaust condition, a DSA process spin speed, an ambient gas flow, a solvent evacuation temperature, a DSA anneal temperature, a DSA anneal time, or a DSA processing condition.

### EXAMPLE 5

The method of one of examples 1 to 4, where the controller sends optical sensor data to a fault detection and correction (FDC) system, and receives processed optical sensor data back from the FDC system.

### EXAMPLE 6

The method of one of examples 1 to 5, where the optical sensor is a laser transceiver, where the optical sensor data is a train of interference fringes, and further including, at the controller, converting the optical sensor data to the property of the film.

### EXAMPLE 7

The method of one of examples 1 to 6, where determining the drying metric includes determining an evaporation rate of a component in the film based on the optical sensor data.

### EXAMPLE 8

The method of one of examples 1 to 7, where the optical sensor includes a plurality of optical sensors spaced apart above the substrate, where obtaining the optical sensor data includes receiving optical sensor data from the plurality of optical sensors, the method further including: converting the optical sensor data to a film property uniformity across the substrate.

### EXAMPLE 9

A method of processing a plurality of wafers includes loading a substrate into a module with a volatile organic compounds (VOC) sensor, processing the substrate in the module to modify a film formed over the substrate, obtaining VOC sensor data from the VOC sensor during the processing, and adjusting a process parameter of the processing at a controller based on the VOC sensor data.

### EXAMPLE 10

The method of example 9, where adjusting the process parameter includes: providing a feed back signal to adjust the process parameter for processing a subsequent substrate, determining an end point of the processing and terminating the processing, providing a feed forward signal to adjust a recipe for a subsequent process for the substrate, or providing a feed forward signal to adjust a recipe for a current process.

### EXAMPLE 11

The method of one of examples 9 or 10, further including: obtaining optical sensor data from an optical sensor during the processing, the optical sensor being disposed in the module, where adjusting the process parameter includes adjusting the process parameter based on the optical sensor data.

### EXAMPLE 12

The method of one of examples 9 to 11, further including: correlating the optical sensor data with the VOC sensor data; and performing, at the controller, a first correlation between a concentration of volatile organics obtained from the VOC sensor data with a property of the film obtained from optical sensor data or a second correlation between a change in the concentration of volatile organics with a change in the property of the film or a third correlation between a change in concentration of volatile organics and a duration of a process step in the processing.

### EXAMPLE 13

The method of one of examples 9 to 12, where adjusting the process parameter of the processing includes: converting the VOC sensor data to an ambient condition in the module during the processing or a property of the film; and based on the ambient condition or the property of the film, adjusting the process parameter.

### EXAMPLE 14

The method of one of examples 9 to 13, where the module includes a coating module and adjusting the process parameter includes adjusting a coating process parameter of the coating module, or where the module includes a bake module and adjusting the process parameter includes adjusting a bake process parameter of the bake module.

### EXAMPLE 15

The method of one of examples 9 to 14, where processing the substrate includes performing a spin-coating process.

### EXAMPLE 16

The method of one of examples 9 to 15, further including comparing, at the controller, the VOC sensor data to stored golden sensor data or to a stored endpoint threshold, where adjusting the process parameter of the processing includes adjusting the process in response to determining that a difference between stored golden sensor data and the VOC sensor data exceeds a predetermined value, or terminating the process in response to determining that the VOC sensor data crosses the stored endpoint threshold.

### EXAMPLE 17

A method of processing a plurality of wafers includes loading a substrate into a module with an edge bead sensor, processing the substrate in the module to modify a film formed over the substrate. The film includes an edge bead at an edge of the substrate. The method further includes obtaining edge bead sensor data from the edge bead sensor during the processing, and adjusting a process parameter of the processing at a controller based on the edge bead sensor data.

### EXAMPLE 18

The method of example 17, where the edge bead sensor includes an optical sensor.

### EXAMPLE 19

The method of one of examples 17 or 18, where adjusting the process parameter of the processing includes adjusting the process parameter of the processing for a subsequent substrate.

### EXAMPLE 20

The method of one of examples 17 to 19, where adjusting the process parameter of the processing includes adjusting a width of a portion of the film removed by the processing, a width of an edge bead hump, a height of the edge bead hump, or a slope of the edge bead hump.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a plurality of substrates, the method comprising:
loading a substrate onto a coating track;
moving the substrate into a module of the coating track;
performing a process to modify a film formed over the substrate;
obtaining, at a controller, optical sensor data from an optical sensor, the optical sensor data comprising a measurement of a property of the film;
determining a drying metric based on the property of the film; and
based on the determined drying metric, adjusting a process parameter of the process.

2. The method of claim 1, wherein adjusting the process parameter comprises:
providing a feed back signal to adjust the process parameter for processing a subsequent substrate,
determining an end point of the processing and terminating the processing,
providing a feed forward signal to adjust a recipe for a subsequent process for the substrate, and
providing a feed forward signal to adjust a recipe for a current process.

3. The method of claim 1, wherein the module comprises a coating module, a bake module, or a solvent anneal baker.

4. The method of claim 1, wherein performing the process comprises performing a directed self-assembly (DSA) coating process, and wherein adjusting the process parameter of the process comprises adjusting a solvent saturation time, a solvent saturation temperature, a solvent saturation concentration, a solvent evacuation initiation time, a solvent evacuation rate, a solvent evacuation duration, a DSA exhaust condition, a DSA process spin speed, an ambient gas flow, a solvent evacuation temperature, a DSA anneal temperature, a DSA anneal time, or a DSA processing condition.

5. The method of claim 1, wherein the controller sends optical sensor data to a fault detection and correction (FDC) system, and receives processed optical sensor data back from the FDC system.

6. The method of claim 1, wherein the optical sensor is a laser transceiver, wherein the optical sensor data is a train of interference fringes, and further comprising, at the controller, converting the optical sensor data to the property of the film.

7. The method of claim 1, wherein determining the drying metric comprises determining an evaporation rate of a component in the film based on the optical sensor data.

8. The method of claim 1, wherein the optical sensor comprises a plurality of optical sensors spaced apart above the substrate, wherein obtaining the optical sensor data comprises receiving optical sensor data from the plurality of optical sensors, the method further comprising:
converting the optical sensor data to a film property uniformity across the substrate.

9. A method of processing a plurality of wafers, the method comprising:
loading a substrate into a module with-a volatile organic compounds (VOC) sensor;
processing the substrate in the module to modify a film formed over the substrate;
obtaining VOC sensor data from the VOC sensor during the processing; and
based on the VOC sensor data, adjusting a process parameter of the processing at a controller.

10. The method of claim 9, wherein adjusting the process parameter comprises:
providing a feed back signal to adjust the process parameter for processing a subsequent substrate,
determining an end point of the processing and terminating the processing,
providing a feed forward signal to adjust a recipe for a subsequent process for the substrate, or
providing a feed forward signal to adjust a recipe for a current process.

11. The method of claim 9, further comprising:
obtaining optical sensor data from an optical sensor during the processing, the optical sensor being disposed in the module, wherein adjusting the process parameter comprises adjusting the process parameter based on the optical sensor data.

12. The method of claim 11, further comprising:
correlating the optical sensor data with the VOC sensor data; and
performing, at the controller, a first correlation between a concentration of volatile organics obtained from the VOC sensor data with a property of the film obtained from optical sensor data or a second correlation between a change in the concentration of volatile organics with a change in the property of the film or a third correlation between a change in concentration of volatile organics and a duration of a process step in the processing.

13. The method of claim 9, wherein adjusting the process parameter of the processing comprises:
converting the VOC sensor data to an ambient condition in the module during the processing or a property of the film; and
based on the ambient condition or the property of the film, adjusting the process parameter.

14. The method of claim 9, wherein the module comprises a coating module and adjusting the process parameter comprises adjusting a coating process parameter of the coating module, or wherein the module comprises a bake module and adjusting the process parameter comprises adjusting a bake process parameter of the bake module.

15. The method of claim 9, wherein processing the substrate comprises performing a spin-coating process.

16. The method of claim 9, further comprising comparing, at the controller, the VOC sensor data to stored golden sensor data or to a stored endpoint threshold, wherein adjusting the process parameter of the processing comprises adjusting the process in response to determining that a difference between stored golden sensor data and the VOC sensor data exceeds a predetermined value, or terminating the process in response to determining that the VOC sensor data crosses the stored endpoint threshold.

17. A method of processing a plurality of wafers, the method comprising:
loading a substrate into a module with an edge bead sensor;
processing the substrate in the module to modify a film formed over the substrate, the film comprising an edge bead at an edge of the substrate;
obtaining edge bead sensor data from the edge bead sensor during the processing; and
based on the edge bead sensor data, adjusting a process parameter of the processing at a controller.

18. The method of claim 17, wherein the edge bead sensor comprises an optical sensor.

19. The method of claim 18, wherein adjusting the process parameter of the processing comprises adjusting the process parameter of the processing for a subsequent substrate.

20. The method of claim 19, wherein adjusting the process parameter of the processing comprises adjusting a width of a portion of the film removed by the processing, a width of an edge bead hump, a height of the edge bead hump, or a slope of the edge bead hump.
